(19) United States
(12) Patent Application Publication
(10) Pub. No.: US 2009/0128220 A1
(43) Pub. Date: May 21, 2009

(54) ISOLATION CIRCUIT

(75) Inventors: Ni-li Chen, Shanghai City (CN); Shih-Hao Liu, Shanghai City (CN)

Correspondence Address: J C PATENTS, INC., 4 VENTURE, SUITE 250, IRVINE, CA, 92618, US

(73) Assignee: INVENTEC CORPORATION, Taipei City, (TW)

(21) Appl. No.: 11/961,151

(22) Filed: Dec. 20, 2007

(30) Foreign Application Priority Data
Nov. 15, 2007 (TW) 96143261

(51) Int. Cl. H03K 17/687

(52) U.S. Cl. 327/434; 327/581

(57) ABSTRACT

An isolation circuit is provided. The isolation circuit is coupled between a master circuit and a slave circuit for isolating or conducting an inter integrated circuit (I2C) signal. While the master circuit has electricity and the slave circuit does not, the isolation circuit isolates the master circuit to prevent the I2C signal being transmitted to the slave circuit. While the master circuit and the slave circuit have electricity, the isolation circuit conducts the master circuit to transmit the I2C signal to the slave circuit. The present invention solves the signal isolation problem between the master and slave circuits, and also improves the operational stability of an I2C bus.

### CROSS-REFERENCE TO RELATED APPLICATION

This application claims the priority benefit of Taiwan application serial no. 96143261, filed on Nov. 15, 2007. The entirety of the above-mentioned patent application is hereby incorporated by reference herein and made a part of this specification.

### BACKGROUND OF THE INVENTION

1. Field of the Invention

The present invention relates to an isolation circuit. More particularly, the present invention relates to an isolation circuit used between a master circuit and a slave circuit in a master-slave circuit structure.

2. Description of Related Art

In a master-slave circuit, operation approaches of pulling up a voltage of an inter integrated circuit (I2C) signal between the master circuit and the slave circuit are different. FIG. 1 is a circuit diagram illustrating a transmission of an I2C signal from a master circuit to a slave circuit. Referring to FIG. 1, a master circuit 10 receives a standby operating voltage P3V3_STBY as a pull-up voltage, and a slave circuit 20 receives operating voltages P3V3 and P5V as the pull-up voltages, wherein the slave circuit 20 includes a level shifter 30, which may shift a voltage level of a signal, and the level shifter 30 is operated in response to the operating voltage P3V3.

In a standby state, i.e. not a normal operation state, only the master circuit 10 is supplied with power, and the slave circuit 20 are not supplied with power. Therefore, in the standby state, the operating voltages P3V3 and P5V are not supplied to the slave circuit 20, and only the operating voltage P3V3_STBY is supplied to the master circuit 10. Namely, in the standby state, the slave circuit 20 has no electricity, and the master circuit 10 has electricity, and therefore the slave circuit 20 may probably pull down voltage levels of a I2C serial data signal I2C_SDA and a I2C serial clock signal I2C_SCL of the master circuit 10, and may cause abnormal operation of the master circuit or unstable of the system.

### SUMMARY OF THE INVENTION

The present invention is directed to an isolation circuit, which may solve a signal isolation problem of an inter integrated circuit (I2C) signal between a master circuit and a slave circuit, and may also improve an operational stability of an I2C bus.

The present invention is directed to an isolation circuit, by which a signal may be isolated or conducted, and when the signal is isolated by the isolation circuit, pulling down of voltage level of the signal may be avoided.

The present invention provides an isolation circuit coupled between a master circuit and a slave circuit for isolating or conducting an I2C signal. When the master circuit has electricity and the slave circuit does not, the isolation circuit isolates the master circuit to prevent the I2C signal being transmitted to the slave circuit. When the master circuit and the slave circuit have electricity, the isolation circuit conducts the master circuit to transmit the I2C signal to the slave circuit.

In an embodiment of the present invention, the master circuit is a main board, and the slave circuit is a backplane.

In an embodiment of the present invention, the isolation circuit is a metal oxide semiconductor switch.

In an embodiment of the present invention, the master circuit is coupled to a first operating voltage, and the isolation circuit and the slave circuit are coupled to a second operating voltage.

According to another aspect, the present invention provides another isolation circuit coupled to a signal output terminal of a master circuit for isolating or conducting a transmission signal of the master circuit. When the master circuit has electricity and the isolation circuit does not, the isolation circuit isolates the signal to avoid voltage level of the signal being pulled down. When the master circuit and the isolation circuit have electricity, the isolation circuit conducts the signal to transmit the signal.

Based on the isolation circuit provided by the present invention, the isolation circuit is coupled between the master circuit and the slave circuit, and when the isolation circuit isolates the signal output from the master circuit, pulling down of the voltage level of the signal may be avoided. Therefore, the isolation circuit may solve a signal isolation problem of the I2C signal between the master circuit and the slave circuit, and may also improve the operational stability of the I2C bus.

In order to make the aforementioned and other objects, features and advantages of the present invention comprehensible, a preferred embodiment accompanied with figures is described in detail below.

### BRIEF DESCRIPTION OF THE DRAWINGS

FIG. 1 is a circuit diagram illustrating a conventional transmission of an I2C signal from a master circuit to a slave circuit.

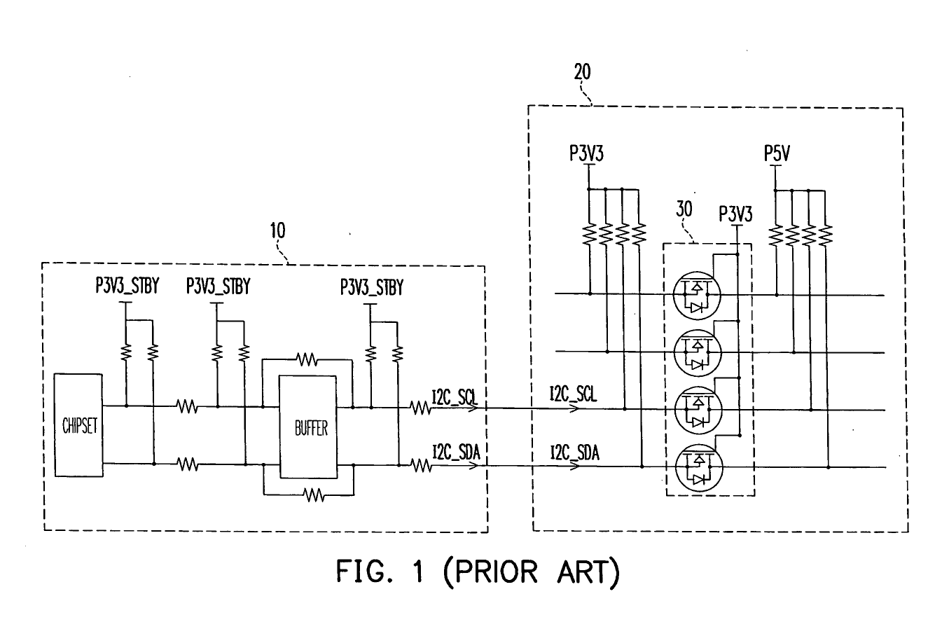

FIG. 2 is a circuit diagram illustrating an isolation circuit coupled between a master circuit and a slave circuit according to an embodiment of the present invention.

### DESCRIPTION OF EMBODIMENTS

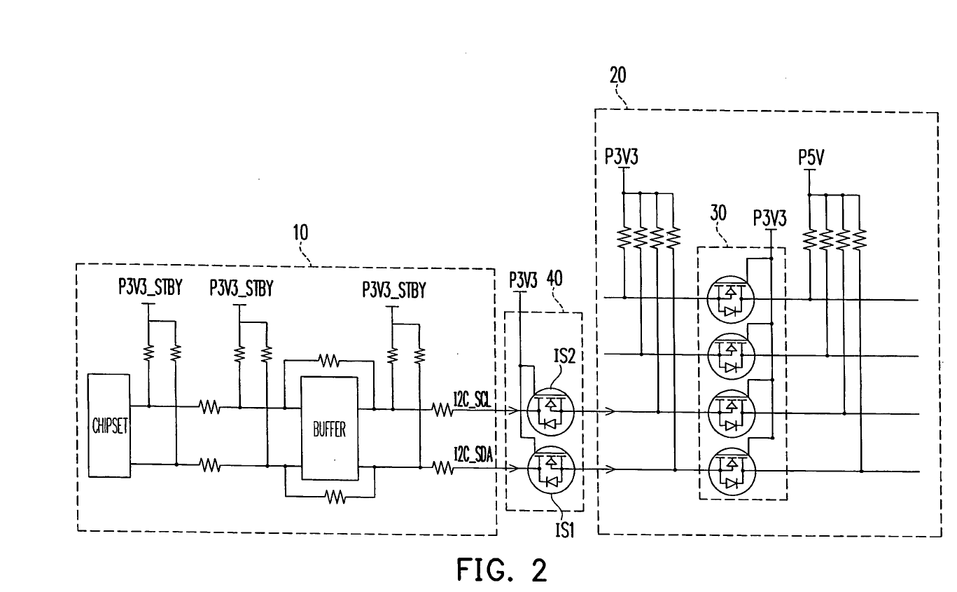

As to a problem of pulling down of an inter integrated circuit (I2C) signal sent from a master circuit, an isolation circuit is applied between the master circuit and a slave circuit for isolating the I2C signal. FIG. 2 is a circuit diagram of an isolation circuit according to an embodiment of the present invention. Referring to FIG. 2, the isolation circuit 40 is coupled between the master circuit 10 and the slave circuit 20. In a standby state, operating voltages P3V3 and P5V are not supplied to the slave circuit 20, namely, the slave circuit has no electricity, and the master circuit 10 has electricity. Therefore, a situation that the slave circuit 20 pulls down voltage levels of an I2C serial data signal I2C_SDA and an I2C serial clock signal I2C_SCL of the master circuit has to be avoided. A standby operating voltage P3V3_STBY is supplied to the master circuit 10, wherein the standby operating voltage P3V3_STBY and the operating voltages P3V3 and P5V are different operating voltages. The isolation circuit 40 may be designed to have a function of isolating the master circuit 10 from transmitting the I2C signal to the slave circuit 20 when the isolation circuit 40 has no electricity, and have a function of conducting the master circuit 10 for transmitting the I2C signal to the slave circuit 20 when the isolation circuit 40 has electricity. Therefore, application of the isolation circuit 40 may avoid abnormal operation of the master-slave circuit and unstable of the system thereof.

In another embodiment, the isolation circuit 40 is designed as switches to control terminals, for example metal oxide semiconductor (MOS) switches. Assuming the isolation circuit 40 is formed by the MOS switches IS1 and IS2, gates of the MOS switches IS1 and IS2 are control terminals of the isolation circuit 40 and are coupled to the operating voltage P3V3, such that whether or not the isolation circuit 40 has electricity may be determined by whether or not the operating voltage P3V3 is supplied. Source and drain of the MOS switch IS1 are coupled between the master circuit 10 and the slave circuit 20 for isolating or conducting the I2C serial data signal I2C_SDA of the master circuit 10; and source and drain of the MOS switch IS2 are coupled between the master circuit 10 and the slave circuit 20 for isolating or conducting the I2C serial clock signal I2C_SCL of the master circuit 10. It should be understood by those skilled in the art that an embodiment of the isolation circuit 40 is not limited to the MOS switches. Moreover, as to the isolation circuit 40 composed of the MOS switches, number of the MOS switches is not limited to that mentioned in the present embodiment, which may be increased or decreased according to the number of the I2C signals.

In addition, in another embodiment, the aforementioned master circuit 10 may be a main board circuit of a computer (not shown), and the slave circuit 20 may be a backplane circuit of the computer, and therefore the isolation circuit 40 may be disposed between the main board circuit and the backplane circuit for isolating or conducting the I2C signal.

Since the isolation circuit 40 is coupled between the master circuit 10 and the slave circuit 20, during normal operation, the master circuit 10, the slave circuit 20 and the isolation circuit 40 are supplied with power, the master circuit 10 may transmit the I2C signal to the slave circuit 20; and during the standby state, the operating voltages P3V3 and P5V are not supplied to the slave circuit 20 and the isolation circuit 40, and therefore the isolation circuit 40 has no electricity, and may isolate the master circuit 10 from transmitting the I2C signal to the slave circuit 20. Therefore, the isolation circuit 40 may prevent the master circuit 10 being influenced by the slave circuit 20 under the standby state.

In summary, based on the isolation circuit provided by the present invention, the isolation circuit is coupled between the master circuit and the slave circuit, and when the isolation circuit isolates the output signal of the master circuit, pulling down of the voltage level of the signal may be avoided. Therefore, the isolation circuit may solve a signal isolation problem between the master circuit and the slave circuit, and may also improve the operational stability of an I2C bus.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An isolation circuit, coupled between a master circuit and a slave circuit for isolating or conducting an inter integrated circuit (I2C) signal, wherein when the master circuit has electricity and the slave circuit does not have electricity, the isolation circuit isolates the master circuit to prevent the I2C signal from being transmitted to the slave circuit, and when the master circuit and the slave circuit have electricity, the isolation circuit conducts the master circuit to transmit the I2C signal to the slave circuit.

2. The isolation circuit as claimed in claim 1, wherein the master circuit is a main board, and the slave circuit is a backplane.

3. The isolation circuit as claimed in claim 1, wherein the isolation circuit is a metal oxide semiconductor switch.

4. The isolation circuit as claimed in claim 1, wherein the master circuit is coupled to a first operating voltage, and the isolation circuit and the slave circuit are coupled to a second operating voltage.

5. An isolation circuit, coupled to a signal output terminal of a master circuit for isolating or conducting a transmission signal of the master circuit, wherein when the master circuit has electricity and the isolation circuit does not have electricity, the isolation circuit isolates the signal to avoid voltage level of the signal being pulled down, and when the master circuit and the isolation circuit have electricity, the isolation circuit conducts the signal to transmit the signal.

6. The isolation circuit as claimed in claim 5, wherein the master circuit is a main board.

7. The isolation circuit as claimed in claim 5, wherein the isolation circuit is a metal oxide semiconductor switch.

8. The isolation circuit as claimed in claim 5, wherein the master circuit is coupled to a first operating voltage, and the slave circuit is coupled to a second operating voltage.
